(19) United States
(12) Patent Application Publication
(10) Pub. No.: US 2013/0256871 A1
(43) Pub. Date: Oct. 3, 2013

(54) SEMICONDUCTOR CHIP DEVICE WITH FRAGMENTED SOLDER STRUCTURE PADS

(71) Applicants: Roden R. Topacio, Markham (CA); Neil McLellan, Austin, TX (US)

(72) Inventors: Roden R. Topacio, Markham (CA); Neil McLellan, Austin, TX (US)

(21) Appl. No.: 13/434,327

(22) Filed: Mar. 29, 2012

(51) Int. Cl. H01L 23/498; H01L 21/60

(52) U.S. Cl. 257/737; 438/613; 438/125; 257/E21.508; 257/E21.511; 257/E23.068

(57) ABSTRACT

Methods and apparatus to inhibit cracks and delaminations in a semiconductor chip solder bump and to reduce pad parasitic capacitance are disclosed. In one aspect, a method of manufacturing is provided that includes forming a first insulating layer over plural conductor pads of a semiconductor chip and forming an opening over each of the conductor pads. An individual solder structure is coupled to the insulating layer. The solder structure has a projection in each of the openings and in electrical contact with one of the plural conductor pads.

### BACKGROUND OF THE INVENTION

1. Field of the Invention

This invention relates generally to semiconductor processing, and more particularly to methods and apparatus for coupling a solder structure to a semiconductor chip input/output site.

2. Description of the Related Art

Flip-chip mounting schemes have been used for several years to mount semiconductor chips to circuit boards, such as semiconductor chip package substrates. In many conventional flip-chip variants, a plurality of solder joints are established between input/output (I/O) sites of a semiconductor chip and corresponding I/O sites of a circuit board. In one conventional process, a solder bump is metallurgically bonded to a given I/O site or pad of the semiconductor chip and a so-called pre-solder is metallurgically bonded to a corresponding I/O site of the circuit board. Thereafter the solder bump and the pre-solder are brought into proximity and subjected to a heating process that reflows one or both of the solder bump and the pre-solder to establish the requisite solder joint.

In one conventional process, the connection of the solder bump to a particular I/O site of a semiconductor chip entails forming an opening in a top-level dielectric film of a semiconductor chip proximate the I/O site and thereafter depositing metal to establish an under bump metallization (UBM) structure. The solder bump is then metallurgically bonded to the UBM structure by reflow. The opening in the dielectric film is shaped with relatively planar sidewalls, that is, without any protrusions or projections. One conventional example uses an octagonal opening. The later-formed UBM structure has an interior wall that matches the planar sidewall configuration of the dielectric opening.

Flip-chip solder joints may be subjected to mechanical stresses from a variety of sources, such as coefficient of thermal expansion mismatches, ductility differences and circuit board warping. Such stresses can lead to crack propagation in the solder joint, particularly at the intermetallic interface between the UBM structure and the solder bump. In the conventional variant just described where the dielectric opening has a planar interior wall, cracks can propagate across the relatively open expanse between opposing or adjacent sidewalls of the UBM structure. Unimpeded crack propagation can lead to solder delamination and joint failure.

Another issue associated with conventional bump pad designs that has the potential to affect device performance is parasitic capacitance between a bump pad and underlying active interconnect traces. Conventional bump pads are typically unitary structures with lateral dimensions that approach or exceed the lateral dimensions of the overlying bumps. Large overlap areas between a conventional unitary bump pad and underlying interconnect traces can introduce latency, particularly as device geometries continue to decrease and operating frequencies increase.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes forming a first insulating layer over plural conductor pads of a semiconductor chip and forming an opening over each of the conductor pads. An individual solder structure is coupled to the insulating layer. The solder structure has a projection in each of the openings and in electrical contact with one of the plural conductor pads.

In accordance with another aspect of an embodiment of the present invention, a method of coupling a semiconductor chip to a circuit board is provided that includes placing plural projections of a first individual solder structure in corresponding plural openings in an insulating layer of the semiconductor chip. Each of the openings is over one of plural conductor pads. The first solder structure is coupled to the circuit board.

In accordance with another aspect of an embodiment of the present invention, an apparatus is provided that includes a semiconductor chip that has plural conductor pads. An insulating layer is on the plural conductor pads. The insulating layer has an opening over each of the plural conductor pads. An individual solder structure is on the insulating layer. The solder structure has a projection in each of the openings and in electrical contact with one of the plural conductor pads.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a semiconductor chip device that includes a semiconductor chip mounted on a circuit board;

FIG. 2 is a sectional view of FIG. 1 taken at section 2-2;

FIG. 3 is an exploded pictorial view of a small portion of the semiconductor chip depicted in FIG. 1;

FIG. 4 is an exploded pictorial view of a small portion of a convention semiconductor chip;

FIG. 5 is a sectional view like FIG. 2, but depicting exemplary passivation structure processing;

FIG. 6 is a sectional view like FIG. 5, but depicting exemplary polymer layer processing;

FIG. 7 is a sectional view like FIG. 6, but depicting additional exemplary polymer layer processing;

FIG. 8 is a sectional view like FIG. 7, but depicting exemplary underbump metal layer processing;

FIG. 9 is a sectional view like FIG. 8, but depicting exemplary solder structure application;

FIG. 10 is a sectional view of FIG. 2 taken at section 10-10;

FIG. 11 is a sectional view like FIG. 10, but depicting an alternate exemplary conductor pad arrangement;

FIG. 12 is a sectional view like FIG. 10, but depicting another alternate exemplary conductor pad arrangement;

FIG. 13 is a sectional view like FIG. 2, but depicting another alternate exemplary conductor pad arrangement;

FIG. 14 is a sectional view like FIG. 2, but depicting another alternate exemplary conductor pad arrangement; and

FIG. 15 is a pictorial view of an exemplary electronic device with an exemplary semiconductor chip device exploded therefrom.

### DETAILED DESCRIPTION OF SPECIFIC EMBODIMENTS

Various embodiments of a semiconductor chip are described herein. One example includes a fragmented solder structure connection pad that utilizes plural pads for a given solder structure instead of just one. The solder structure, an optional UBM layer, and an underlying insulating layer may be tailored for these multi-pad configurations. Parasitic capacitance may be reduced and solder crack propagation may be avoided. Additional details will now be described.

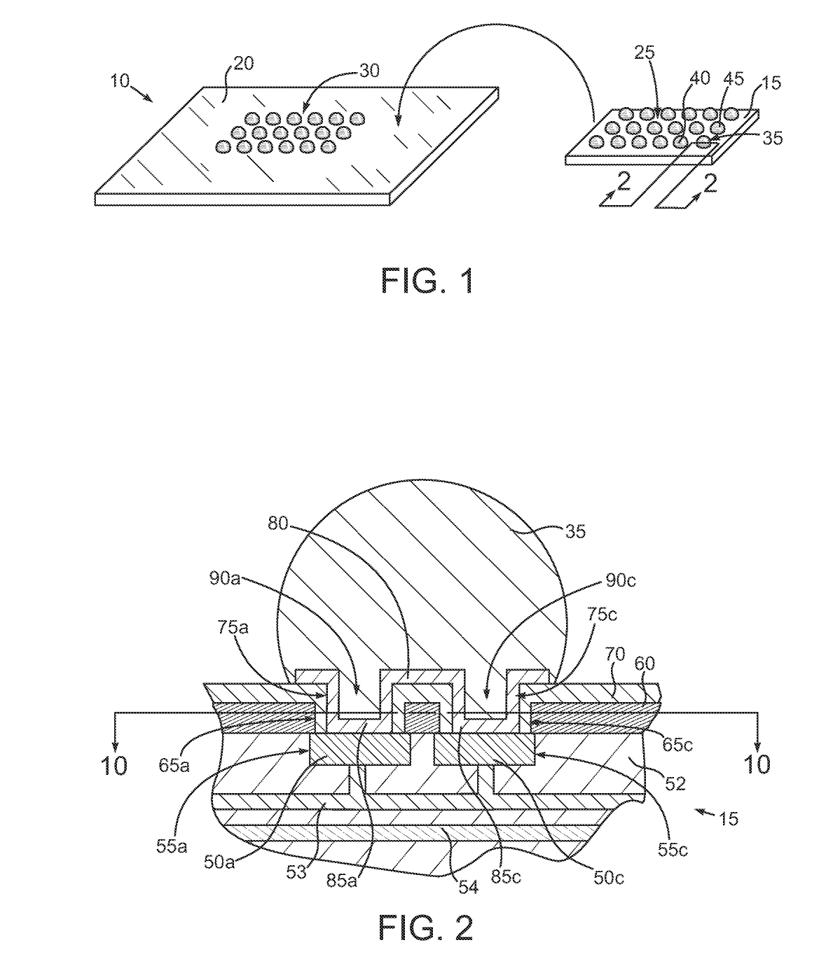

In the drawings described below, reference numerals are generally repeated where identical elements appear in more than one figure. Turning now to the drawings, and in particular to FIG. 1, therein is shown a pictorial view of an exemplary embodiment of a semiconductor chip device 10 that includes a semiconductor chip 15 that may be mounted on a circuit board 20. In this illustrative embodiment, and to illustrate certain features of the semiconductor chip 15, the chip 15 is shown detached and flipped over from its mounting position on the circuit board 20. The semiconductor chip 15 includes multiple solder structures or bumps 25, which are designed to metallurgically bond with the corresponding array of solder structures 30 on the circuit board 20 and form plural solder joints or other type of solder connections when the semiconductor chip 15 is mounted to the circuit board 20. Note that three of the solder bumps 25 are separately labeled 35, 40 and 45. The solder bump 35 will be used to illustrate additional features of the semiconductor chip 15 in conjunction with subsequent figures.

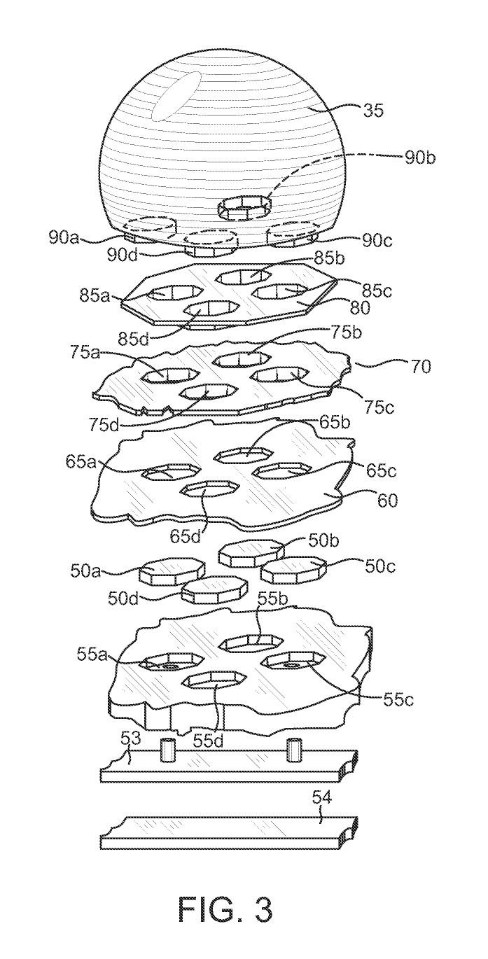

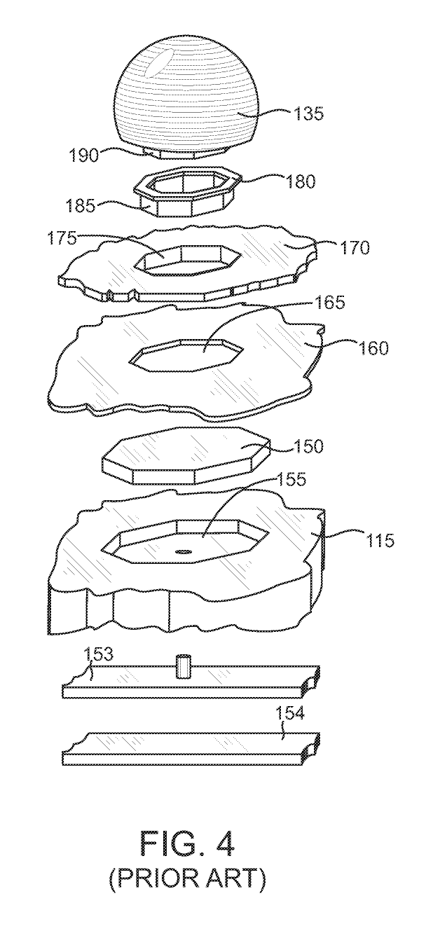

Additional details of the solder bump 35 may be understood by referring now to FIGS. 2 and 3. FIG. 2 is a sectional view of FIG. 1 taken at section 2-2 and FIG. 3 is an exploded pictorial view of a portion of the semiconductor chip 15, the solder bump 35 and various intervening structures. Before turning to FIG. 2 in earnest, it should be noted that section 2-2 passes through a portion of the semiconductor chip 15 that includes the solder bump 35. The following discussion of the solder bump 35 will be illustrative of the other solder bumps 25 and related structures. For simplicity of illustration, the full depth of the semiconductor chip 15 is not depicted and the features thereof are not drawn to scale in FIGS. 2 and 3. In lieu of a unitary bump pad of the type described in the Background section hereof and depicted in FIG. 4, the solder bump 35 is electrically connected to plural, fragmented bump pads 50a, 50b, 50c and 50d. Again note that because of the location of section 2-2, only the pads 50a and 50c are visible in FIG. 2. The portion of the semiconductor chip 15 that is visible in FIGS. 2 and 3 may actually consist of various types of dielectric materials, such as those that may be used in multiple metallization stack schemes. Here, a single dielectric layer 52 is shown, but there may be many. The dielectric layer 52 may be composed of so-called “low-K” materials that favor reduced parasitics between displaced conductor layers. When formed, the pads 50a, 50b, 50c and 50d are positioned in respective openings 55a, 55b, 55c and 55d. The openings 55a, 55b, 55c and 55d may be formed prior to the formation of the pads 50a, 50b, 50c and 50d or result from the initial formation of the pads 50a, 50b, 50c and 50d and the subsequent build up of insulating material around the pads 50a, 50b, 50c and 50d. The skilled artisan will appreciate that the pads 50a, 50b, 50c and 50d may be part of a topmost layer of interconnect metallization and may be connected to various other electrical structures both laterally and vertically. For example, an interconnect layer 53 is connected to the pads 50a and 50c. In addition, another conductor trace 54 is positioned under the interconnect layer 53 and overlaps with the overlying conductor pads 50a, 50b, 50c and 50d. In addition, the skilled artisan will appreciate that somewhere within the confines of the semiconductor chip 15 an active device region with multitudes of integrated circuit elements such as transistors, resistors and others is positioned. The conductor pads 50a, 50b, 50c and 50d may be composed of a variety of conductor materials, such as aluminum, copper, silver, gold, titanium, refractory metals, refractory metal compounds, alloys of these or the like. In lieu of a unitary structure, the conductor pads 50a, 50b, 50c and 50d may consist of a laminate of plural metal layers. However, the skilled artisan will appreciate that a great variety of conducting materials may be used for the conductor pads 50a, 50b, 50c and 50d. Various well-known techniques for applying metallic materials may be used, such as physical vapor deposition, chemical vapor deposition, plating or the like. It should be understood that additional conductor structures could be used.

The pads 50a, 50b, 50c and 50d are top coated with an insulating layer 58, which may be unitary or consist of a passivation structure 60, which includes openings 65a, 65b, 65c and 65d to the underlying conductor pads 50a, 50b, 50c and 50d, and an overlying polymer layer 70. The passivation structure 60 is designed to protect the conductor pads 50a, 50b, 50c and 50d from physical damage and contamination prior to the manufacture of an underbump metallization (UBM) structure and attachment of the solder bump 35. Exemplary materials include silicon dioxide, silicon nitride, polyimide, laminates of these or the like.

A polymer layer 70 may be formed on the passivation structure 60 and includes projections 75a, 75b, 75c and 75d that are recessed and project into the opening 65a, 65b, 65c and 65d and are in contact with at least portions of the pads 50a, 50b, 50c and 50d. The polymer layer 70 is designed to provide a compliant protective layer and thus may be composed of a variety of materials, such as polyimide, benzocyclobutene or other insulating materials such as silicon nitride or the like and may be deposited by spin coating, CVD or other techniques. If desired, the polymer layer 70 may be composed of polyimide infused with photoactive compounds to enable the photolithographic patterning of openings as described below.

An underbump metallization (UBM) structure 80 is formed on the polymer layer 70 with projections 85a, 85b, 85c and 85d that extend down through the projections 75a, 75b, 75c and 75d of the polymer film 70 and establish ohmic contact with the underlying pads 50a, 50b, 50c and 50d. The UBM structure 80 is designed to satisfy a few important objectives, namely, to bond to the overlying solder bump 35 or other solder structure, to establish a conductive interface with an underlying conductor structure, in this case the conductor pads 50a, 50b, 50c and 50d, and to bond as necessary with underlying or surrounding dielectrics, such as the passivation structure 60, all while providing a barrier to the diffusion of solder constituents into underlying conductor structures, which might otherwise degrade those conductor structures. In this illustrative embodiment, the UBM structure 80 may consist of a laminate of plural metallic layers. The number and composition of such layers may be tailored to a particular bumping process, such as printing or plating for example. For example, the UBM structure 80 might be constructed for a printed solder bump 35 as a series of layers applied to the semiconductor chip 15 in succession, such as an adhesion layer of sputtered titanium or titanium-tungsten, followed by a sputtered nickel-vanadium layer, and capped with a sputtered solder-wettable layer of copper or gold. However, in the event that a bump plating process is used to establish the later-formed solder bump 35, then the UBM structure 80 may consist of an adhesion layer of the type described above, followed by a plating seed layer, such as copper deposited by electroless plating or sputter deposition, followed by a nickel or nickel-vanadium barrier layer of the type described above and capped with a plating bar of copper of the like.

The solder bump 35 includes projections 90a, 90b, 90c and 90d, which fill into the recessed projections 85a, 85b, 85c and 85d of the UBM structure 80. The solder bump 35 may be composed of a variety of lead-based or lead-free solders. An exemplary lead-based solder may have a composition at or near eutectic proportions, such as about 63% Sn and 37% Pb. Lead-free examples include tin-silver (about 97.3% Sn 2.7% Ag), tin-copper (about 99% Sn 1% Cu), tin-silver-copper (about 96.5% Sn 3% Ag 0.5% Cu) or the like. Referring again briefly to FIG. 1, the solder structures 30 of the circuit board 20 may be composed of the same types of materials. Optionally, the solder structures 30 may be eliminated in favor of a single solder structure or a solder plus a conducting post arrangement.

Several benefits flow from the fragmented pads 50a, 50b, 50c and 50d. First, the plural pads 50a, 50b, 50c and 50d can provide an I/O site with a smaller overlap area with the underlying conductor trace 54 than a comparable conventional unitary pad. This smaller overlap area reduces the parasitic capacitance between the UBM structure 80 and the pads 50a, 50b, 50c and 50d, which can improve signal speed and decrease latency. Second, the usage of fragmented pads 50a, 50b, 50c and 50d results in a somewhat larger polymer layer 70 that is better able to provide bump stress protection for the underlying low-K insulating material 52. Third, the segregation of the solder projections 90a, 90b, 90c and 90d prevents solder crack propagation that might otherwise cascade across the entire interface between the solder bump 35 and the UBM 80.

It may be useful at this point to contrast a conventional conductor stack and solder bump structure. Attention is now turned to FIG. 4, which is an exploded pictorial view like FIG. 3, but of a conventional semiconductor chip 115 and a solder bump 135 coupled thereto. Like FIG. 3, FIG. 4 depicts a small portion of the semiconductor chip 115 which may constitute dielectric material. Here, a unitary conductor pad 150 is formed on the semiconductor chip 115. The interconnect traces 153 and 154 may be like the corresponding structures 53 and 54 depicted in FIGS. 2 and 3. The conductor pad 150 is exploded from a recess 155 that may be formed before or after the pad 150. A passivation structure 160 is formed over the pad 150 and patterned with a suitable opening 165 that leads to the pad 150. A polymer film 170 is formed on the passivation structure and with a projection 175 that projects through the opening 165 and seats on the pad 150 below. A UBM structure 180 is formed on the polymer film 160 and with a projection 185 that projects through the projection 175 of the polymer film 70 and establishes ohmic contact with the underlying unitary conductor pad 150. Here, and as noted above, there may be a larger overlap area between the unitary conductor pad 150 and the underlying conductor trace 154 and thus a higher level of parasitic capacitance than is provided by the advantageous structure depicted in FIGS. 2 and 3 and described above. In addition, the polymer layer 170 is smaller than the polymer layer 70 depicted in FIGS. 2 and 3. An exemplary numerical example will illustrate. One example of the conventional conductor pad 150 may have width of 91.8 microns and top surface area of 6981 square microns. In contrast, the pads 50a, 50b, 50c and 50d may have widths of 34 microns, individual top surface areas of 957 square microns, and a combined top surface area (for overlap considerations) of 3828 square microns, which represents a 46% reduction in area versus the conventional pad 150.

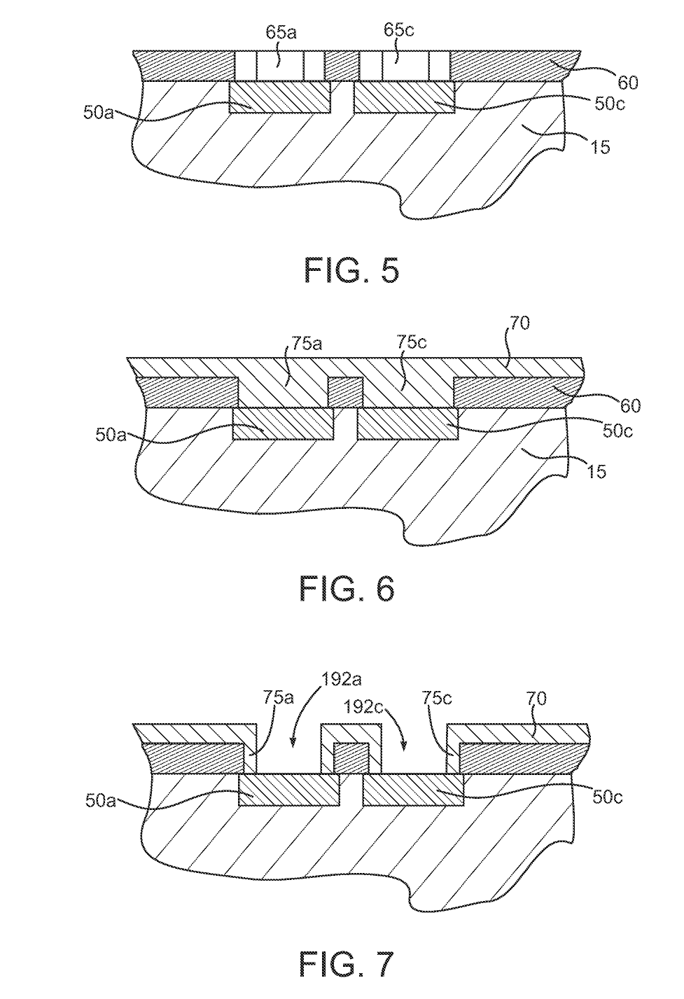

An exemplary method for fabricating the solder bump structure 35 and the related intermediary films and layers depicted in FIGS. 2 and 3 may be understood by referring now to FIGS. 5, 6, 7, 8 and 9 and initially to FIG. 5. The following exemplary process will be illustrative of the other solder bumps 25 depicted in FIG. 1 for example. Referring initially to FIG. 5, and keeping in mind that only two of the plural conductor pads 50a, 50b, 50c and 50d are depicted in FIG. 5, the conductor pads 50a and 50c may be formed on the semiconductor chip 15 from a variety of conductor materials, such as aluminum, copper, silver, gold, titanium, refractory metals, refractory metal compounds, alloys of these or the like. In lieu of a unitary structure, the conductor pads 50a, 50b, 50c and 50d may consist of a laminate of plural metal layers. However, the skilled artisan will appreciate that a great variety of conducting materials may be used for the conductor pads 50a, 50b, 50c and 50d. Various well-known techniques for applying metallic materials may be used, such as physical vapor deposition, chemical vapor deposition, plating or the like.

The passivation structure 60 may be next applied to the semiconductor chip 15 as a blanket layer or laminate of layers. Following application, the openings 65a and 65c may be formed in the passivation structure 60. The opening 65a and 65c may be formed in a variety of ways, such as wet or dry etching, laser drilling or others. Suitable masking may be used.

As shown in FIG. 6, the polymer film 70 may be applied to the passivation structure 60 so as to fill the openings 65a and 65c and thus define the projections 75a and 75c. Spin coating or other application techniques may be used to apply the polymer film 70. Note that the projections 75a and 75b fill the cavities 65a and 65c of the passivation structure 60. In order to expose portions of the underlying conductor pads 50a and 50c, the polymer film 70 may be lithographically patterned. This may be done in a variety of ways depending on the composition of the polymer film 70. A polyimide polymer film 70 may be infused with a photoactive compound(s) lithographically patterned. In this illustrative embodiment, the polymer film 70 does contain photoactive compounds. A suitable non-contact mask (not shown) may be applied to the polymer film 70 and the polymer film 70 subjected to exposure and developing to produce holes 192a and 192c. A bake cure is next performed on the polymer film 70. Of course, chemical etching, laser drilling or other patterning techniques could be used.

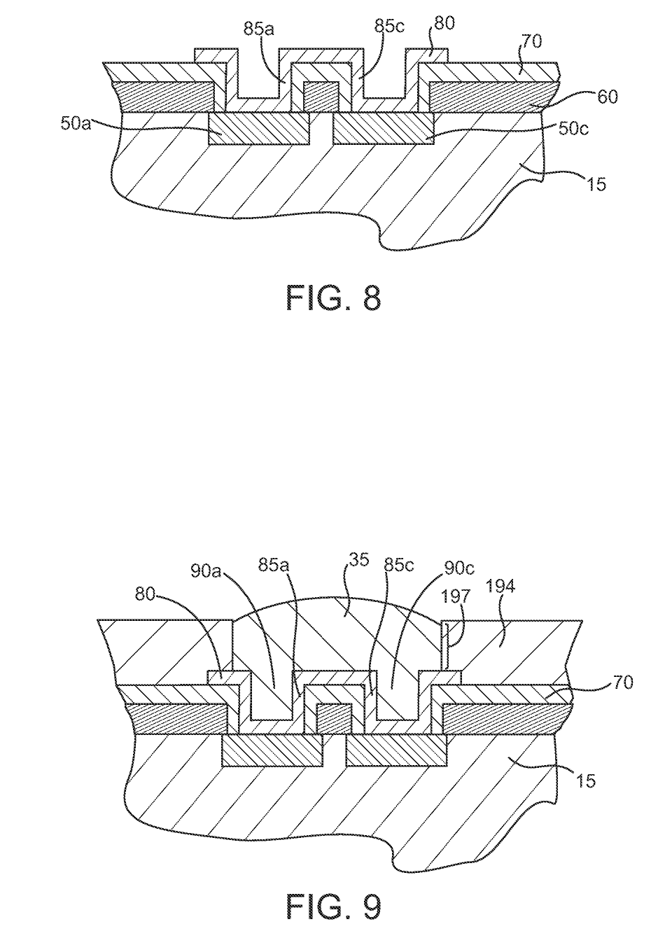

Next, and as shown in FIG. 8, the UBM structure 80 may be fabricated using the techniques described above. The UBM structure 80 may be initially formed as a blanket that is subsequently patterned. A suitable etch mask (not shown) may be applied, particularly at the location slated for eventual solder bump attachment and thus in alignment with the conductor pads 50a, 50b, 50c and 50d, and an etch process performed to reduce the size of the UBM structure 80. Following the etch, the UBM structure 80 is patterned like an island but with the projections 85a and 85c. The etch chemistry and process suitable for etching the UBM structure 80 will depend upon the composition of the constituent layers. For example, a copper solder-wettable layer and nickel or nickel-vanadium layer may be etched using a hot phosphoric acid etch and a titanium adhesion layer may be etched using an HF etch. Although technically more complex, an island-like UBM structure 80 layer could be alternatively constructed by selective material addition, such as by lift-off processing. Following the etch, the mask (not shown) may be removed by ashing, solvent stripping or the like. The mask (not shown) may be formed from positive tone resist, a hard mask or a non-contact mask. Patterning may be by well-known photolithography.

Next and as shown in FIG. 9, a suitable lithography mask 194 may be formed on the UBM structure 80 and the polymer film 70 and patterned with an appropriate opening 197 that exposes at least a significant percentage of the UBM structure 80. Thereafter, the solder bump 35 may be applied with the mask 194 in place either by printing or plating as desired. If a printing process is used, then an appropriate stencil (not shown) may be used to initially apply the solder bump 35. Thereafter, a suitable reflow process may be used to temporarily liquefy the solder bump 35 and yield the structure for the solder bump 35 depicted in FIGS. 1, 2 and 3. If a plating process is used, then the need for a stencil is eliminated and the solder bump 35 may be plated using the mask 194. Whether by plating or printing, the solder projections 90a and 90c fill the UBM projections 85a and 85c. The semiconductor chip 15 may be coupled to the circuit board 20 and a reflow performed to merge the solder structures 25 and 30 into solder joints.

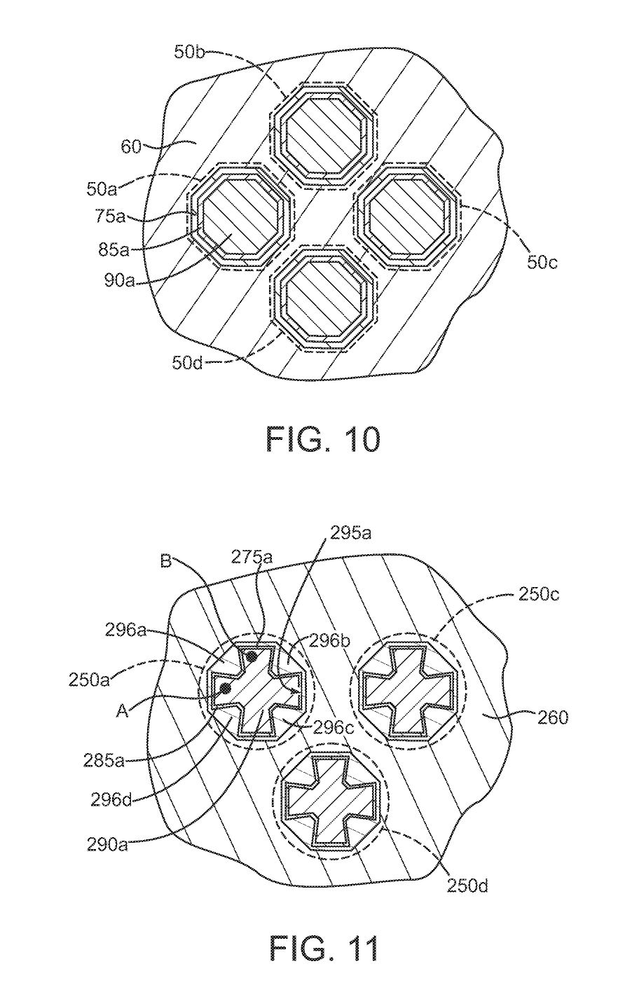

In the foregoing illustrative embodiments, a set of four conductor pads 50a, 50b, 50c and 50d, each with an octagonal footprint, is used to establish electrical contact between the solder bump 35 and the underlying semiconductor chip 15. However, considerable flexibility is envisioned for pad footprint shape, UBM projection footprint shape and solder projection footprint shape, as well as the number of pads for a given I/O site. Before discussing alternatives to this basic form, it will be useful to briefly review the footprint of the pads 50a, 50b, 50c and 50d. In this regard, attention is now turned to FIG. 10, which is a sectional view of FIG. 2 taken at section 10-10. The following description of the conductor pad 50a and overlying structures will be illustrative of the other conductor pads 50b, 50c and 50d. Note that the conductor pad 50a (covered by passivation 60 and thus shown in dashed) has a footprint with a generally octagonal shape. The visible portions of the polymer layer projection 75a and the UBM layer projection 85a have footprints with similar octagonal shapes, and the solder projection 90 has a footprint with an octagonal shape.

The basic scheme in FIG. 10 utilizes four conductor pads 50a, 50b, 50c and 50d to establish ohmic contact with a solder bump. However, numbers conductor pads that number other than four and with footprints other than octagonal may be used, and the footprints of stacked structures need not match. In this regard, attention is now turned to FIG. 11, which is a sectional view like FIG. 10, but depicting an alternate exemplary embodiment where three conductor pads 250a, 250c and 250d are formed with circular footprints and in a triangular pattern. The following description of the conductor pad 250a and its related structures will be illustrative of the other conductor pads 250c and 250d and their related structures. The polymer film projection 275a may have an octagonal external footprint, but an undulating internal profile as described in more detail below. The UBM projection 285a has a generally cross-shaped footprint that contains a correspondingly cross-shaped solder projection 290a. This arrangement hardens the intermetallic interface between the solder bump projection 290a and the UBM projection 285a. As noted above, the solder bump 35 (see FIGS. 2 and 3) may be subjected to significant strains that can impact the integrity of that intermetallic interface. If a fracture occurs near that intermetallic interface, and the types of strains associated with the thermal cycling or other types of stresses continue, solder delamination can occur. However, the polymer projection 275a is fabricated with an interior wall 295a that includes plural protrusions 296a, 296b, 296c and 296d that provide a contoured interior profile. The UBM projection 285a tracks this contoured interior profile. In this way, many avenues for crack propagation are cut off by the contoured internal profile. For example, a crack originating proximate point A but propagating toward point B will be prevented from complete propagation by way of the inwardly projecting protrusion 296a. In this illustrative embodiment, the protrusions 296a, 296b, 296c and 296d may have a generally trapezoidal shape. However, it should be understood that the number and shape of the protrusions 296a, 296b, 296c and 296d can be varied. The pad 250a and the structures related thereto depicted in FIG. 11 may be fabricated using the same general techniques described above.

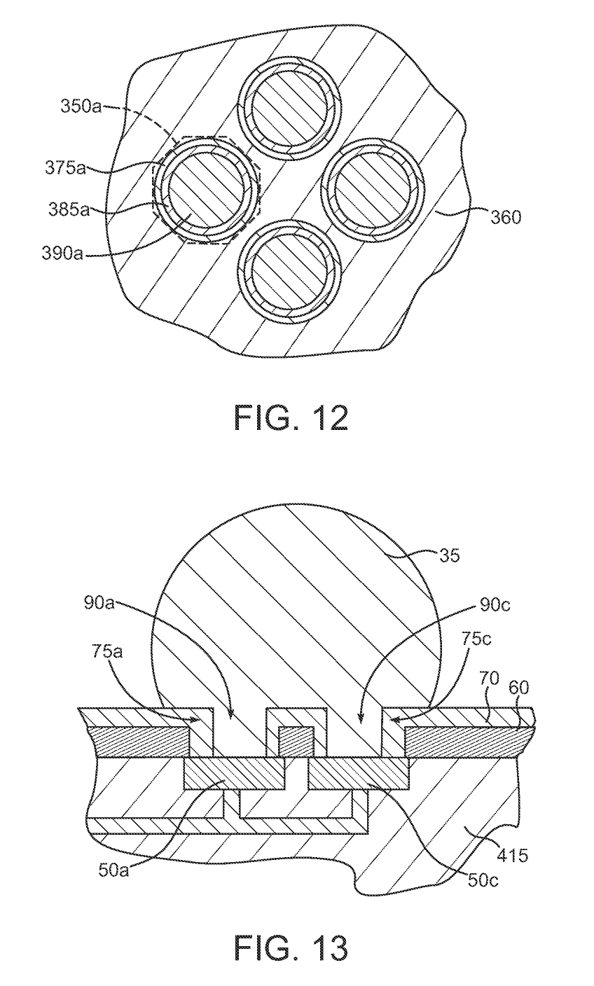

Another alternate exemplary embodiment of a conductor pad 350a may be understood by referring now to FIG. 12, which is a sectional view like FIG. 11. Here, the pad 350a may have a footprint with an octagonal shape while the polymer projection 375a and UBM projection 285a have footprints with cylindrical shell shapes and the solder projection 390a may have generally circular footprints as shown. Like the other embodiments, the projection 375a of the polymer material is surrounded laterally by the passivation structure 360. Many other alternative arrangements in terms of footprints and pad numbers are envisioned.

Any of the disclosed embodiments might be fabricated without a UBM. FIG. 13 is a sectional view like FIG. 2, but of an alternate exemplary embodiment in which a UBM is not used. A semiconductor chip 415 may be configured like the semiconductor chip 15 described above in conjunction with FIGS. 1-3 and 5-9 and thus include the solder structure or bump 35, the fragmented conductor pads 50a and 50c, the passivation structure 60 and the polymer layer 70 and the projections 75a and 75c thereof. However, the solder projections 90a and 90c are positioned in the projections 75a and 75b and make contact with the pads 50a and 50b without an intervening UBM. This may be possible where the properties of the solder bump 35 and the conductor pads 50a and 50b do not require protection from constituent migration and contamination.

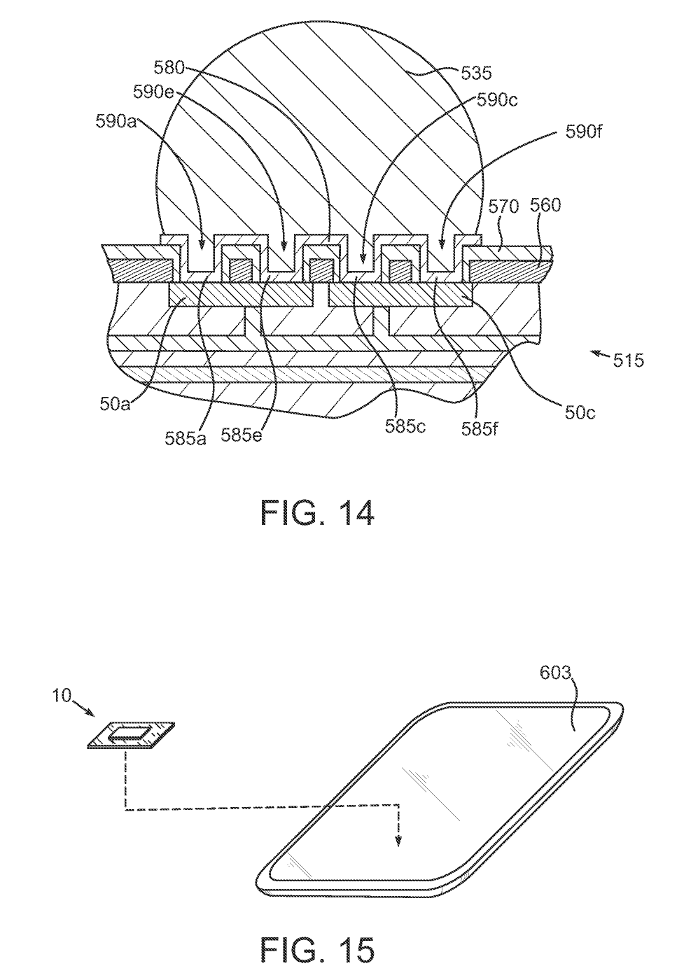

In still another alternative exemplary embodiment, multiple UBM and solder projections may extend to a given fragmented conductor pad. FIG. 14 is a sectional view like FIG. 13, but of such an alternative. A semiconductor chip 515 may be configured like the semiconductor chip 15 described above in conjunction with FIGS. 1-3 and 5-9 and thus include the fragmented conductor pads 50a and 50c. However, the passivation structure 560, the polymer layer 570, and the UBM 580 are fabricated to provide multiple UBM projections 585a and 585e to the conductor pad 50a and multiple UBM projections 585c and 585f to the conductor pad 50c. The solder bump 535 has corresponding solder projections 590a and 590e connected to the pad 50a and other projections 590c and 590f connected to the pad 50c. Of course, more than two solder projections may be dedicated to a given fragmented pad 50a or 50c.

Any of the disclosed embodiments of the semiconductor chip devices may be mounted in another electronic device 603 as shown in FIG. 15. Here, the semiconductor chip device 10 is shown exploded from the electronic device 603. The electronic device 603 may be a computer, a digital television, a handheld mobile device, a personal computer, a server, a memory device, an add-in board such as a graphics card, or any other computing device employing semiconductors.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
forming a first insulating layer over plural conductor pads of a semiconductor chip; and
forming an opening over each of the conductor pads; and
coupling an individual solder structure to the insulating layer, the solder structure having a projection in each of the openings and in electrical contact with one of the plural conductor pads.

2. The method of claim 1, comprising fabricating an underbump metal layer having a projection in each of the openings and in contact with one the plural conductor pads, one of the solder structure projections being positioned in each of the projections.

3. The method of claim 1, wherein the insulating layer comprises a passivation structure and a polymer layer on the passivation structure.

4. The method of claim 1, wherein the plural conductor pads have a first footprint with a shape and the solder structure projections have second footprints with the shape.

5. The method of claim 1, wherein the plural conductor pads have a first footprint with a shape and the solder structure projections have second footprints with a different shape.

6. The method of claim 1, wherein at least one of the openings defining an interior wall of the insulating layer that includes plural protrusions.

7. The apparatus of claim 1, wherein the plural conductor pads comprise an input/output site.

8. A method of coupling a semiconductor chip to a circuit board, comprising:
placing plural projections of a first individual solder structure in corresponding plural openings in an insulating layer of the semiconductor chip, each of the openings being over one of plural conductor pads;
coupling the first solder structure to the circuit board.

9. The method of claim 8, wherein the coupling the first solder structure comprises coupling a second solder structure to the circuit board and thereafter coupling the first solder structure to the second solder structure.

10. The method of claim 8, wherein the circuit board comprises a semiconductor chip package substrate.

11. The method of claim 8, wherein conductor pads comprise an input/output site.

12. The method of claim 8, comprising placing each of the solder structure projections in a projection of an underbump metal layer in each of the openings and in contact with one the plural conductor pads.

13. An apparatus, comprising:
a semiconductor chip having plural conductor pads;
an insulating layer on the plural conductor pads, the insulating layer having an opening over each of the plural conductor pads; and
an individual solder structure on the insulating layer, the solder structure having a projection in each of the openings and in electrical contact with one of the plural conductor pads.

14. The apparatus of claim 13 comprising an underbump metal layer having a projection in each of the openings and in contact with one the plural conductor pads, one of the solder structure projections being positioned in each of the projections.

15. The apparatus of claim 13, wherein the insulating layer comprises a passivation structure and a polymer layer on the passivation structure.

16. The apparatus of claim 13, wherein the plural conductor pads have a first footprint with a shape and the solder structure projections have second footprints with the shape.

17. The apparatus of claim 13, wherein the plural conductor pads have a first footprint with a shape and the solder structure projections have second footprints with a different shape.

18. The apparatus of claim 13, wherein at least one of the openings defining an interior wall of the insulating layer that includes plural protrusions.

19. The apparatus of claim 13, wherein the plural conductor pads comprise an input/output site.

20. The apparatus of claim 13, comprising a circuit board coupled to the semiconductor chip.
